(19) United States
(12) Patent Application Publication
(10) Pub. No.: US 2023/0101021 A1
(43) Pub. Date: Mar. 30, 2023

(54) EUV PHOTOMASK ARCHITECTURES FOR PATTERNING OF INTEGRATED CIRCUITS

(71) Applicant: Astrileux Corporation, Richmond, CA (US)

(72) Inventor: Supriya JAISWAL, San Diego, CA (US)

(21) Appl. No.: 17/956,042

(22) Filed: Sep. 29, 2022

Related U.S. Application Data
(60) Provisional application No. 63/250,032, filed on Sep. 29, 2021.

(51) Int. Cl. G03F 1/24; G03F 1/26; G03F 1/62; G03F 1/60

(52) U.S. Cl. CPC G03F 1/24; G03F 1/26; G03F 1/62; G03F 1/60

(57) ABSTRACT

The present disclosure provides masks suitable for Extreme Ultraviolet (EUV) and X-ray lithography by including a non-reflective region combined with a reflective multilayer. This non-reflective region replaces a typical absorber layer used to provide the pattern for integrated circuits.

### CROSS-REFERENCE TO RELATED APPLICATIONS

The present application claims the benefit of U.S. provisional application No. 63/250,032, filed Sep. 29, 2021, the content of which is hereby incorporated by reference in its entirety.

### BACKGROUND OF THE INVENTION

Optical lithography systems are commonly used for fabrication, for example, of devices. The resolving power of such systems is proportional to the exposure wavelength. Thus, shorter wavelengths can improve resolution in fabrication. Extreme ultraviolet lithography (EUVL) uses electromagnetic radiation at extreme ultraviolet (EUV) wavelengths (approximately 120 nanometers to 0.1 nanometers). Accordingly, photons at these wavelengths have energies in the range of approximately 10 electron volts (eV) to 12.4 keV (corresponding to 124 nm and 0.1 nm, respectively). Extreme ultraviolet wavelengths may be generated artificially by devices such as plasma and synchrotron light sources. Using EUV wavelengths for lithography has potential advantages of reducing feature sizes in devices such as semiconductor chips as well as in other applications such as polymer electronics, solar cells, biotech, and medical technologies.

In EUV Lithography systems a Reflective Photomask or mask or reticle is used to transfer the integrated circuit chip architecture onto the wafer. Typically the EUV reflective mask consists of a substrate, reflective layer, capping layer, absorber layer and optionally other layers. The absorber layer is patterned by an e-beam lithography to represent the pattern or the mathematical complement of the pattern of the integrated circuit to be transferred into the wafer.

The selection of reflective materials used in elements of lithography are often severely limited. Traditional material combinations consist of a Molybdenum-Silicon multilayer which theoretically produces up to 67% reflectivity. The Mo—Si layer is used on the mirrors, collector and photomasks in EUV lithography systems. Other traditional multilayer combinations include barrier layers such as Boron Carbide, and Carbon, collectively referred to as the state of the art.

Typical materials used in an absorber layer pattern may consist of Tantalum Nitride, Tantalum OxyNitride, Nickel or Cobalt or NiAl₃. These materials are chosen to maximize absorption and minimize reflection amplitude or phase change between light reflected from the absorber layer and the multilayer. More recent materials include Ruthenium, which is used in a low n mask application, where n is the real part of the refractive index, and is less than 1 at EUV wavelengths.

There are several known side effects of absorber layer patterns. Absorber layer patterns create a shadow on the reflective layer, known as the 3D shadow mask effect. They also have a finite thickness, typically around 70 nm which has a tendency to trap material defects, particles around 20 nm or so, on the reflective layer which often need to be repaired.

3D mask effects can result in unwanted feature-size dependent focus, imaging aberrations and pattern placement shifts when the absorber layer pattern is transferred to the wafer. In addition, large differences in focus between 1D and 2D features, limit the yield process windows in lithography. Mask shadowing effect is the consequence of the EUV mask absorber height and the non-telecentric, off axis illumination at the mask level, which modulates the intensity projected on to the wafer. Features perpendicular to the direction off illumination (vertical features) are shifted relative to features parallel (horizontal features) to the direction of illumination. At the wafer level, this causes a differential horizontal-vertical critical dimension bias and image shifts. Horizontal-Vertical bias is the systematic difference in linewidth between closely located horizontally and vertically oriented resist features, and is caused by astigmatism, phase error across the pupil, and a difference in best focus.

A phase shifted absorber mask is also used to create a pattern, where adjacent regions are shifted in phase relative to each other, to create a cancellation in the light to achieve the desired pattern. Conventional methods might include reflective/absorbing combinations, or reflective multilayers where the multilayer is etched all the way through to the underlying substrate, and the underlying substrate then absorbs the radiation, or reflective regions adjacent to absorbing regions. This is not effective in overcoming the 3D mask effect, or the shadow mask effect, because the height difference between the top surface and the absorbing surface is the entire thickness of the multilayer stack, or the thickness of the absorber stack.

Improved absorber masks and methods of their production are needed to reduce 3D mask effects or shadow mask effects.

### BRIEF SUMMARY OF THE INVENTION

In one aspect, the present disclosure provides an extreme ultraviolet mask, including a substrate; and a reflective layer and a diffraction grating. The diffraction grating, comprises regions of reflecting and non-reflecting regions, may be formed on top of the reflective layer, or may be submerged within the reflective layer. The reflective layer includes a bottom surface in contact with the substrate, and a top surface.

### BRIEF DESCRIPTION OF THE DRAWINGS

FIG. 1 provides a mask comprising reflecting regions and non-reflecting regions.

FIG. 2 provides metals with useful extinction coefficients (k) and refractive indices (n).

FIG. 3 compares reflectivity values for four different above surface mask configurations, materials TaN, Ni, Ru and low n low k. A low reflectivity value is desired for a non-reflecting region NR in a diffraction grating.

FIG. 4 provides a 3D mask and a 2D (planar) mask comprising submerged non-reflective regions and illustrates the Zeff parameter of an EUV mask. I₀ is the intensity of the incident light. Iₘₐₓ is the intensity of the light in the reflecting region (R). Iₘᵢₙ is the intensity of the light in the non-reflecting region (NR). R/NR ratio=Iₘₐₓ/Iₘᵢₙ.

FIG. 5 provides comparison on above surface and submerged mask designs. The submerged designs can be low Zeff designs, 2D planar design or have mask bias.

FIG. 6 provides reflectivity performance comparison for a low n high k e.g. PtO₂ mask compared to Ru and TaN. The R/NR ratio is significantly larger in the case of the low n high k mask. (8.5) This produces a higher NILS value.

FIG. 7 provides an illustration of an absorber free mask, with a diffraction grating submerged into a multilayer. The Reflective Region is air. The non-reflective region is the ML coating itself which has an effective refractive index<1

FIG. 8 provides an illustration of an absorber free mask, with a metal, metal oxide, or carbonates, nitrate, sulfate integrated into the multilayer creates contrast between air and the ML and therefore an enhanced NILS. The R/NR ratio is 10.4. This produces a NILS value of 4.1. The reference for the state of the art in EUV Lithography is 2.0.

FIG. 9 illustrates Contrast and NILS as used herein.

### DETAILED DESCRIPTION OF THE INVENTION

### I. General

The present disclosure provides lithography masks for use with extreme ultraviolet and X-ray radiation. These masks incorporate non-reflective regions either located above or submerged within a reflective multilayer that can provide the image contrast necessary to transfer the image to the wafer through photoresist (a light sensitive imaging material). The use of non-reflective regions to define the pattern of the Integrated Circuit (IC) can remove the need for a patterned absorber layer above the reflective multilayer in the integrated mask architecture. By incorporating non-reflective regions submerged within the reflective multilayer, the top surface of the reflective multilayer can be substantially planar, so there are essentially no features extending above the top surface of the reflective multilayer that can introduce shadows. The non-reflective regions can be introduced into the reflective layer by modifying selected regions beneath the top surface of the reflective multilayer to either deflect light into the multilayer rather than to the wafer, or to absorb light. Consequently, the mask shadow effect arising from a shadow cast by the finite non-zero height of the absorbance layer relative to the plane of the reflective multilayer can be reduced. Further, with removal of the absorber layer, or reduced height, 3D waveguideing, image placement errors, 3D diffraction effects, and dead space on the mask can be reduced.

The architecture of a typical embodiment of an EUV reflective photomask consists of a substrate, a reflective layer and a capping layer (also known as the EUV mask blank) and an absorber layer. The reflective layer may consist of a multilayer, e.g. a molybdenum silicon multilayer or other type reflective layer responsible for reflecting EUV radiation. A ruthenium capping layer is optional, but can serve to protect the multilayer from degradation during operation and defects arising from the plasma source and other elements in the lithography system.

The absorber layer can be patterned to represent desired the IC design that needs to be transferred to the wafer. Typically patterning of the absorber layer is achieved by a e-beam lithography process, using e-beam photoresist, e-beam exposure and etching of the absorber layer. This creates finite structures submerged within the absorber layer, which are responsible for selectively blocking EUV radiation in the desired physical location, and allowing light to reflect in others where the absorber structure is absent.

Absorber layer selection depends on a number of parameters, including thickness, material n and k value, which represent the real and imaginary part of the refractive index at the desired wavelength, top surface reflection amplitude and overall absorption amplitude. In certain embodiments, the phase change between light reflected from the multilayer and light reflected from the absorber layer is be minimized. In certain embodiments, the shadow on the reflective layer is minimized, which minimizes the effective reflective area and creates a dead space. Absorber layers of finite thickness can create waveguiding effects, another manifestation of the 3D mask effect, which can be undesirable.

Competing goals exist in the material selection of the absorber layer. On one hand complete absorption is desired to prevent light transferring into the reflective layer below, which would then be undesirably reflected. This could be achieved by very thick absorber structures. However, thicker absorber structures produce larger shadows on the reflective portion of the mask, more wave-guiding and increase the propensity of defect trapping. More absorbing materials may also be used, e.g. gold and silver, but typically result in more top surface reflection from the absorber layer which is undesirable. TaN represents one of the better material selections for absorber layer, which effectively compromises absorption and top surface reflection with a finite of thickness of 70 nm. Ni and Co, and various combinations and compounds thereof are also materials of choice.

In lithography the finite absorber layer pattern deteriorates on wafer performance and the quality of the pattern transferred to the wafer. Phase differences create contrast loss, shifts in depth of focus, and the Bossung Curve (CD v depth of focus), Horizontal and Vertical Bias and resolution. Therefore several approaches already exist to reduce the thickness of the absorber layer and phase difference. None of these completely remove the shadow effect, or prevent waveguiding or defect trapping.

In certain embodiments, this disclosure relates to an EUV photomask architecture without the use of an absorber layer. Specifically the reflective layer or reflective coating is patterned to provide both reflection in certain physical locations and to turn off or suppress reflectivity in other selective physical locations. Turning off reflectivity is distinguished from transmission or absorption explicitly, and relates to using materials to confining light to the reflective physical locations. Turning off reflectivity is more desirable than having an absorber layer, as it achieves an improved image contrast without wave-guiding, shadowing or defect trapping, and increases overall reflectivity from the mask i.e. reflectivity from the reflective regions and therefore the overall transmission of the lithography system.

In certain embodiments, reflectivity can be reduced or eliminated by creating adjacent regions of higher refractive index and lower refractive index, e.g. a diffraction grating. In this way, light can be confined into the higher refractive index region. Higher contrast provides more the confinement. The higher refractive index region may be for example air or silicon. The person of skill will recognize that no confinement is perfect, and light may leak into the low refractive index region and travel into the multilayer below it. Low contrasting adjacent regions endure more leakage. Therefore, in certain embodiments, high contrast is provided in the real part of refractive index as well as some absorption in low refractive index material. Therefore, low n and high k materials are desirable in the non-reflecting region. Additionally, very low n materials, n<0.89 are also desirable in the non-reflecting region. This is distinguished from a low k material where k<0.3 and a high n material where n>0.9. In the current state of the art, TaN is considered a high n, high k material. n=0.94 and k=0.37 at 13.5 nm. Ru, as a pure metal, is considered a low n low k material e.g. n=0.89 and k=0.017 at 13.5 nm. In particular embodiments, where the threshold for low n is <0.89, Ru is not considered to have adequately low enough n. A pure Ru absorber layer or non-reflecting region causes light leakage and high top surface reflectivity which is undesirable for a non-reflecting region. Particular embodiments herein utilize materials which push the performance beyond the state of the art materials. i.e either n<0.89 or n<0.89 and k>0.3.

Methods to make adjacent reflective and non-reflective regions include a combination of techniques involving deposition, e-beam patterning and etching. Deposition may be carried out in tools under vacuum e.g. ion beam deposition, sputtering, atomic layer deposition, physical vapor deposition, molecular beam epitaxy, chemical vapor deposition. Etching includes reactive ion etching and atomic layer etching. E-beam pattering includes electron beam lithography, photo lithography and other well-known mask writing techniques.

Image contrast is defined as the ratio of the intensity of light reflected from the non-reflective region to light to the intensity of light reflected from the reflective region. It represents the effectiveness of the non-reflective region to suppress reflected light relative to the reflective region, and provide a sharp edge for patterning the wafer, enabling high resolution and pattern fidelity. High refractive index contrast between adjacent regions and light confinement results in good image contrast.

### I. Definitions

The abbreviations used herein have their conventional meaning within the chemical and lithographic arts.

“Substrate” refers to any material capable of supporting the multilayer of the present disclosure. Representative substrates can be metals, metal alloys, semiconductors, composites, silicon, polymers, glass, low thermal expansion substrates and others.

“Reflective multilayer” refers to a material that substantially reflects extreme ultraviolet (EUV) radiation, such as radiation less than 250 nm to less than 10 nm. The reflective multilayer material can also reflect X-ray radiation. Materials suitable for reflective multilayer of the present disclosure are described herein. The reflective multilayer layer may include reflective (R) regions and non-reflective (NR) regions, i.e., regions that do not substantially reflect EUV and X-ray radiation.

“Refractive index” refers to the ratio of the speed of light in a medium to the speed of light in a vacuum. In practice, refractive index is a complex number, such that refractive index=n+i*k. (n) designates the real part of the refractive index and (k) designates the imaginary part of the refractive index also known as the extinction coefficient.

“Angle of incidence” refers to the angle between the incoming radiation and the normal or normal incidence, the line perpendicular to the surface at the point of incidence. The angle of incidence can be any suitable angle. The angle of incidence for EUV lithography can be 6°.

“Metal” refers to elements of the periodic table that are metallic and that can be neutral, or negatively or positively charged as a result of having more or fewer electrons in the valence shell than is present for the neutral metallic element. Metals useful in the present disclosure include the alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Mg, Tc, Ru, Rh, Pd, Ag, Cd, La, Hf, Ta, W, Re, Os, Ir, Pt, Au, Hg, Al and Ac. Post-transition metals include Al, Ga, In, Ti, Ge, Sn, Pb, Sb, Bi, and Po. Rare earth metals include Sc, Y, La, Ce, Pr, Nd, Sm, Eu, Gd, Tb, Dy, Ho, Er, Tm, Yb and Lu. One of skill in the art will appreciate that the metals described above can each adopt several different oxidation states, all of which are useful in the present disclosure. In some instances, the most stable oxidation state is formed, but other oxidation states are useful in the present disclosure. Compounds of transition metals may also be used e.g. TiN, RuO₂, PtO₂. Metals and compounds may be deposited by e-beam deposition, thermal evaporation, PVD, CVD, ALD, or PECVD, MBE, sputtering or ion beam deposition.

In some embodiments, the reflective multilayer and its integrated component is or comprises one or more transition metals, including Mo, Ru. Ta, Pt, Pd, Te, Nb, Tc, Re, Os, Rh, W, C, Ag, and their respective compounds, e.g., oxides, nitrates, nitrides, carbonates, fluorides, chlorides, sulfates, compounds, mixtures and alloys, their dielectrics, Si, and air. As set forth in this disclosure, the contemplated EUV mask includes a reflective ML made of a metal having a lower “n” value and a higher k value than the reflective (R) region. In some embodiments, the reflective ML metal has an n of less than 0.89, less than 0.88, less than 0.87, less than 0.86, less than 0.85, or less than 0.84. In some embodiments, the reflective ML metal has a k greater than zero, between 0.03 and 0.10, between 0.03 and 0.08, or between 0.03 and 0.06. Examples of candidate materials and their n and k values at 13.5 nm are shown in the table below.

| Material | n (13.5 nm) | k (13.5) nm |
|---|---|---|
| Air | 1.0 | 0.0 |
| Si | 0.99 | 0.002 |
| TaN | 0.94 | 0.03 |
| Mo | 0.92 | 0.006 |
| Ru | 0.89 | 0.017 |
| RuO₄ | 0.84 | 0.05 |
| PtO₂ | 0.85 | 0.08 |
| RuNO₃ | 0.84 | 0.05 |

Illumination conditions for the contemplated EUV mask include any suitable illumination condition. In some embodiments, the illumination conditions for the contemplated EUV mask include plane wave, dipole, asymmetrical dipole, quasar, hexapole, leaf, conventional, or any litho scanner pupil illumination condition. The off-axis illumination (OAI) may be from 5 to 11 degrees. In some embodiments, the OAI is 6 degrees.

“Transparent material” refers to a material that is transparent to EUV radiation. Representative transparent materials include silicon and silicon dioxide, graphene, carbon nanotubes, gases, H₂, He, Argon, N₂, silicides, and silicene.

A pellicle, if necessary, may be attached directly to the top surface of the EUV mask, or in close proximity of the top surface, and conformally to plane of a photomask containing a submerged non-reflecting region (e.g. a submerged absorber layer). Compared to the state of the art where the absorber plane is above the multilayer plane, the pellicle as applied to the present disclosure completely prevents particles entering the photomask on the reflective region. The pellicle may be vertically integrated as part of the full mask architecture.

“Capping layer” refers to a layer on top of the reflective multilayer that is used to protect the reflective multilayer from particles that can accumulate on the mask over time. Any suitable material can be used in the capping layer of the present disclosure, such as ruthenium and other transition metals.

“Absorber layer” or “absorbing layer” refers to a layer on top of the reflective multilayer, and typically on top of the capping layer, that absorbs EUV radiation. The absorbance layer covers only selected portions of the reflective multilayer. Thus, an image contrast is formed between the regions of the mask having the absorber layer and those without, enabling the transfer of an image to the wafer.

“Diffraction grating” refers to an optical component having a periodic structure in one, two or three dimensions, that diffracts light from a single direction into multiple directions. The diffraction grating can be made of any suitable material. The diffraction, the grating may also be unevenly spaced, a non-uniform diffraction grating. In this case the period may change from one feature to the next. This typical in real masks.

“Image contrast” or “reflectivity” is defined as the ratio of the intensity of light reflected from the reflective region to light to the intensity of light reflected from the non-reflective region.

“Refractive index” refers to the ratio of the speed of light in a medium to the speed of light in a vacuum. In practice, refractive index is a complex number, such that refractive index=n+i*k. (n) designates the real part of the refractive index and (k) designates the imaginary part of the refractive index. The magnitude of the refractive index changes with wavelength.

“Extinction coefficient (k)” refers to the rate of diminution of transmitted light via scattering and absorption in a medium.

A high k absorber layer is a material with a high absorption, and a high numerical value for k, the imaginary part of the refractive index.

A low n absorber layer is a material with a high absorption, and a low numerical value for n, the real part of the refractive index. At EUV wavelengths n is typically less than 1, e.g. silicon is 0.99 and sometimes less than 0, e.g. Ru is 0.89 at a wavelength of 13.5 nm Low n masks are typically reflective due to the large contrast in the real part of the refractive index from air.

Low n, high k mask refers to masks which have a non-reflecting layer or an absorber layer that is made from a material that has both a high value of k and low value of n.

“Phase difference” refers to the difference between the phase of the reflected wavefront emanating from the reflective region and the phase of the wavefront emanating from the non-reflective or absorbing region. Phase differences are achieved by vary thing the thickness of the layer.

Phase shifting mask refers to a mask containing low n and/or high k materials, in which a phase cancellation occurs between reflecting and non-reflecting regions due to a 180 degrees or π (3.1415) phase difference.

### III. Extreme Ultraviolet Lithography Mask

Provided herein are extreme ultraviolet (EUV) masks comprising an architecture having an increased throughput gain with an increase in normalized image log-slope NILS and a dose reduction.

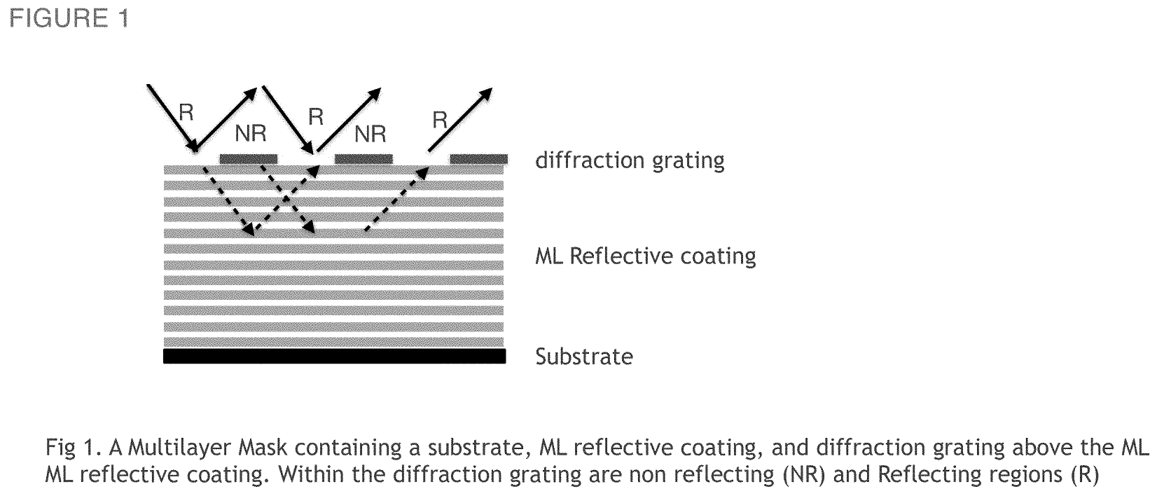

In one embodiment, provided herein are extreme ultraviolet masks comprising a substrate and a reflective multilayer (ML). In particular embodiments, the ML comprises a reflective (R) region with a non-reflective (NR) region made from a material that has a low n value. In particular embodiments, the ML comprises a reflective (R) region with a non-reflective (NR) region made from a material that has a low n value and high k value. In certain embodiments, the n and k values are at EUV wavelengths, including 13.3-13.7 nm and 13.5 nm. In certain embodiments, the multilayer region comprises a bottom surface in contact with the substrate and a top surface. The reflective and non-reflective regions described herein form a diffraction pattern on top or above of the reflective multilayer. The reflective region may be air. The non-reflective region may comprise a metal, including its compounds or mixtures. for instance as shown in FIG. 1

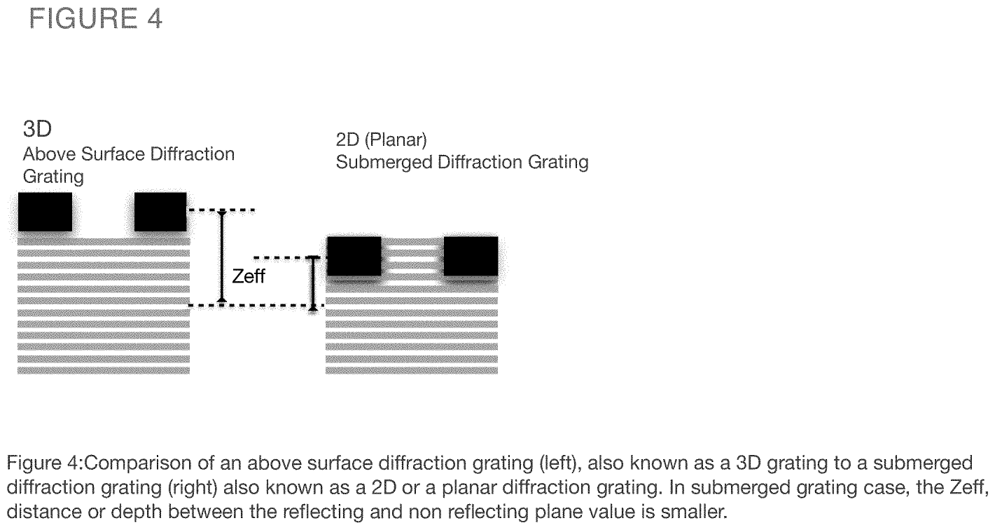

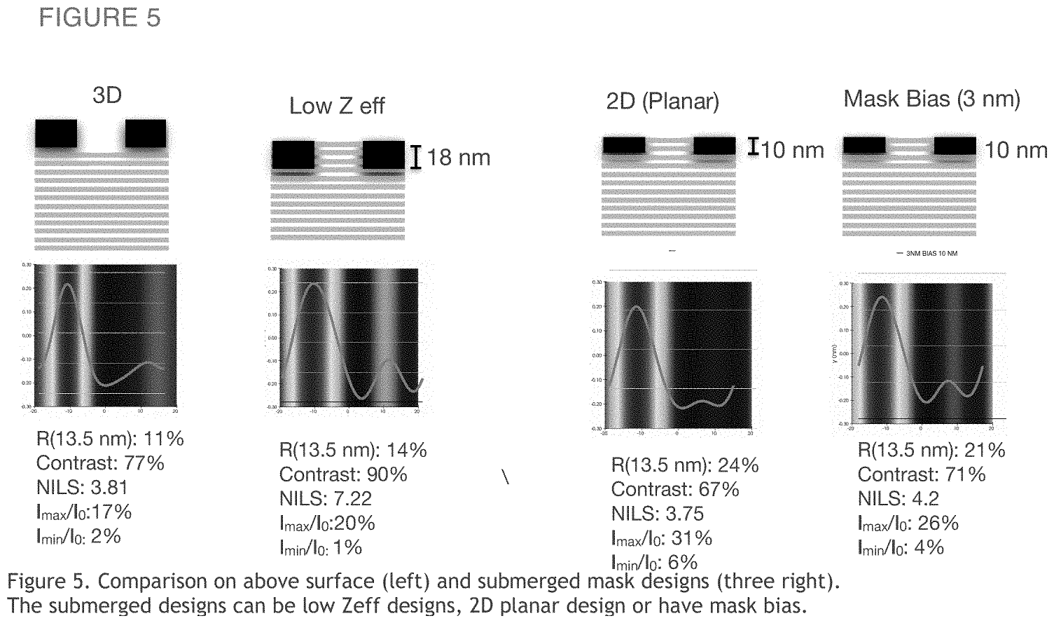

In another embodiment, provided herein are extreme ultraviolet masks comprising a substrate and a reflective multilayer (ML). In particular embodiments, the ML comprises having a reflective (R) region and a non-reflective (NR) region submerged therein. In particular embodiments, the multilayer region comprises a bottom surface in contact with the substrate and a top surface. The reflective and non-reflective region described here form a diffraction pattern submerged with the reflective multilayer, for instance as shown in FIG. 4 and FIG. 5.

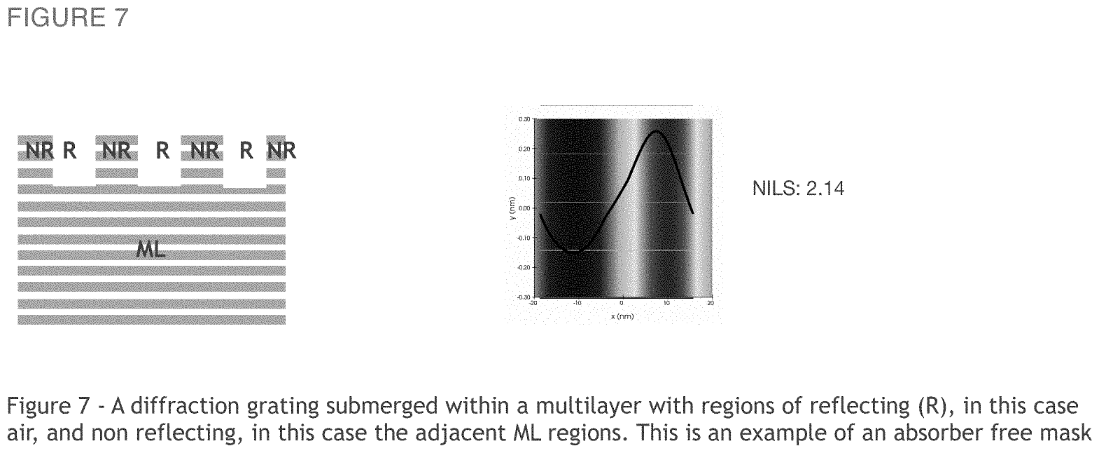

FIG. 7 provides an example of this configuration of the diffraction grating, having air or silicon as the reflective region, submerged in the multilayer and the multilayer as the non-reflective region.

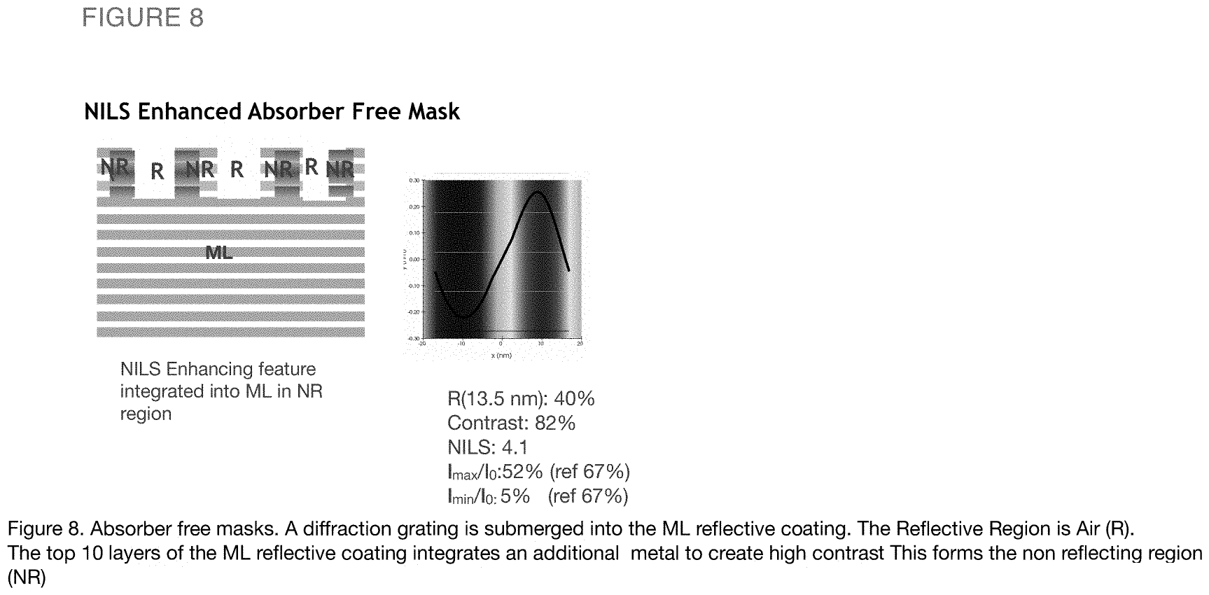

FIG. 8 provides another example of this configuration of the diffraction grating, having have air or silicon as the reflective region, submerged within the multilayer and metal, including its compounds or mixtures integrated in the multilayer as the non-reflective region.

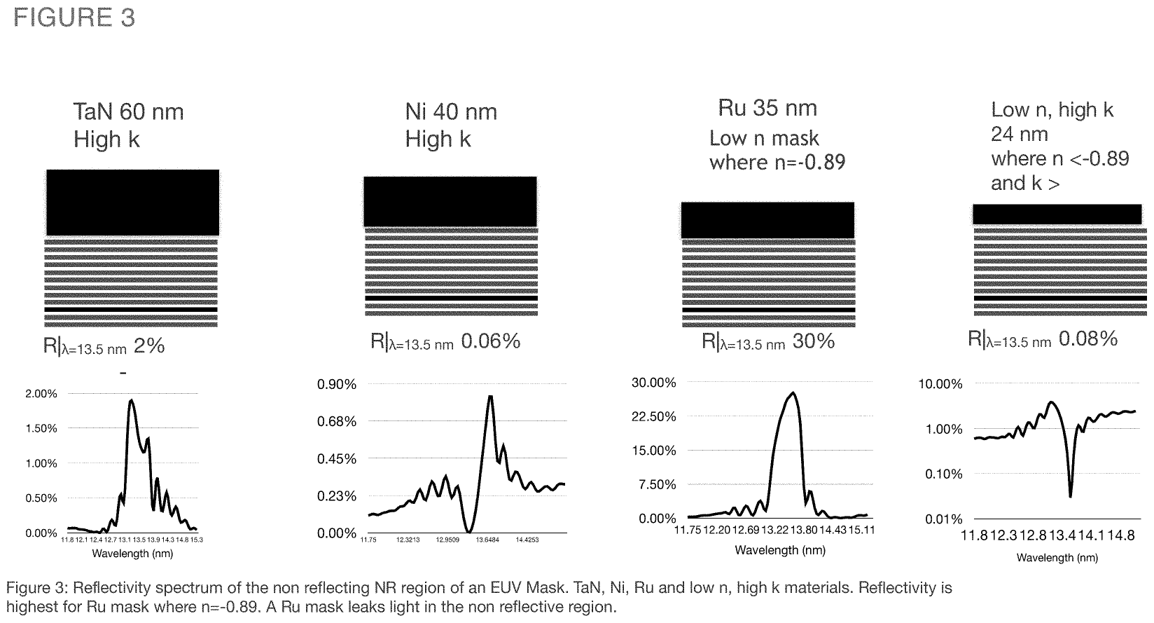

FIG. 3 provides another example of this configuration of the diffraction grating, having the multilayer as the reflective region and metal, including its compounds or mixtures submerged in the multilayer as the non-reflective region.

In particular embodiments, wherein the reflectivity of the reflective (R) region is at least 4.126 times greater than the reflectivity of the non-reflective (NR) region. In certain embodiments, the reflectivity of the R region is at least 5 times greater than the reflectivity of NR region. In certain embodiments, the reflectivity of the R region is at least 1.5 times greater than the reflectivity of NR region. In certain embodiments, the reflectivity of the R region is at least 2.0 times greater than the reflectivity of NR region. In certain embodiments, the reflectivity of the R region is at least 8 times greater than the reflectivity of NR region.

Submerged indicates that a substantial portion of the NR region is below the top surface of the ML. In certain embodiments, at least 50% of the NR region is below the top surface of the ML. In certain embodiments, at least 75% of the NR region is below the top surface of the ML. In certain embodiments, substantially all of the NR region is below the top surface of the ML. In certain embodiments, a substantial portion of the NR region is below the top surface and above the bottom surface of the ML.

Above surface indicates that a substantial portion of the NR region is above the top surface of the ML. In certain embodiments, at least 50% of the NR region is above the top surface of the ML. In certain embodiments, at least 75% of the NR region is above the top surface of the ML. In certain embodiments, substantially all of the NR region is above the top surface of the ML. In certain embodiments, a substantial portion of the NR region is above the top surface and above the bottom surface of the ML.

In certain embodiments, the NR region comprises a low n material. In certain embodiments, the NR region comprises a low n and high k material. The plane containing the material may be referred to as an absorber layer.

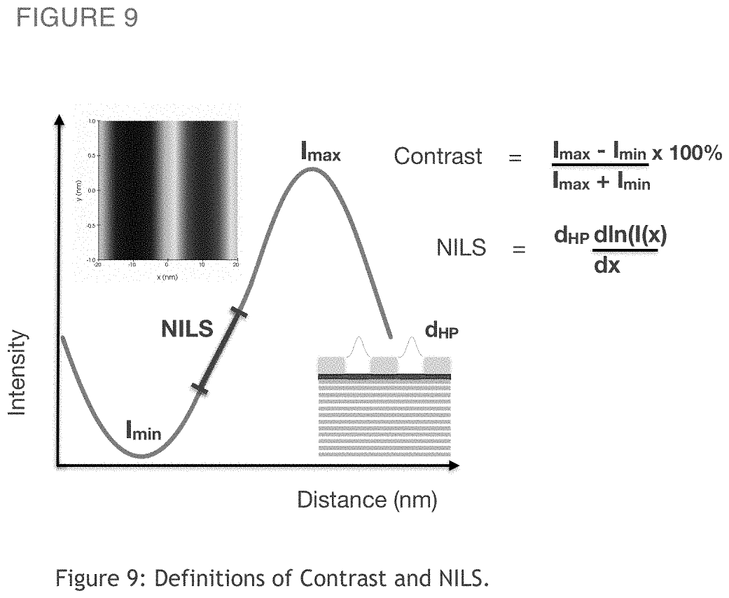

As referenced throughout this disclosure, image contrast is a metric of image quality which may be measured using the normalized image log-slope (NILS). NILS or the image contrast is defined as the ratio of the intensity of light reflected from the non-reflective region to light to the intensity of light reflected from the reflective region. Image contrast or NILS represents the effectiveness of the non-reflective region to suppress reflected light relative to the reflective region, and provide a sharp edge for patterning the wafer, enabling high resolution and pattern fidelity. NILS is illustrated in FIG. 9. NILS is inversely proportional to the square root of the dose.

In certain embodiments, the disclosure relates to an element that can be used in a light exposure system, wherein the system or subsystem includes a light source to transmit light having a wavelength.

In another embodiment, the disclosure relates to an element that can be used in a light exposure system containing a photomask, mirror or lens, substrate element. The system or subsystem can include a light source to transmit light having a wavelength. The element can include a material having plurality of structural features or one or more material combinations.

The mask of the present disclosure is suitable for use with extreme ultraviolet and X-ray radiation. Extreme ultraviolet (EUV) radiation includes radiation from less than 250 nm to less than 10 nm, or from about 193 nm to less than 10 nm, or from about 124 nm to about 10 nm, or from about 20 nm to about 10 nm. In some embodiments, the radiation has a wavelength from 250 nm to 1 nm. In some embodiments, the radiation has a wavelength from 193 nm to 1 nm. In some embodiments, the radiation has a wavelength from 124 nm to 10 nm. In some embodiments, the radiation has a wavelength of about 13.5 nm.

The present disclosure also provides an EUV mask where the non-reflective (NR) region includes a diffraction grating to diffract light into the reflective multilayer.

The diffraction grating can be one, two or three-dimensional in nature. In some embodiments, the diffraction grating is one-dimensional, two-dimensional or three-dimensional. In some embodiments, the diffraction grating is one-dimensional. In some embodiments, the diffraction grating is two-dimensional. In some embodiments, the diffraction grating is three-dimensional.

The diffraction grating can be prepared from any suitable material, including metals, metal oxides, and other materials. The diffraction grating can be prepared from the same material as the reflective layer, or a different material. The diffraction grating can be prepared from the same material as the non-reflective region, or a different material. In some embodiments, the diffraction grating includes at least one component of molybdenum, niobium, ruthenium, platinum, palladium, rhenium, osmium, silver, nickel, cobalt, copper, nickel, gold, copper, tungsten, tantalum oxide or tungsten oxide, or NiAl₃. In some embodiments, the diffraction grating is prepared from the same material as the reflective layer. In some embodiments, the diffraction grating is prepared from the same material as the non-reflective region.

In some embodiments, the contemplated EUV mask includes a diffraction grating made of air.

A diffraction grating is prepared using either optical lithography, e-beam lithography, grayscale lithography or etched rulings. In e-beam (electron beam) or optical lithography a sensitive material such as photoresist or e-beam resist material is prepared on the surface and then patterned via exposure to a laser source or electron beam source. The resist is then cross linked, and unexposed regions are removed via wet chemical processing. The pattern resist region acts as a soft mask, and via an etching process the pattern is transferred into the wafer. A blazed grating, e.g. with a saw tooth profile may be created using grayscale lithography where the dose of the exposure beam is varied as a during exposure to create a depth profile in the resist. Alternatively the blazed grating may be produced by non-isotropic etching, or by orienting the grating at an angle. The diffraction grating may also be created by a combination of etching, self assembly and deposition for 3D gratings, or through an EUV/DUV lithography and directed self assembly combination.

After patterning the diffraction grating by e beam lithography, reactive ion etching or atomic layer etching is used to inscribe the pattern in the underlying material. This may either be in the absorber layer in the case of the above surface diffraction grating, or in the multilayer in the case of the submerged grating.

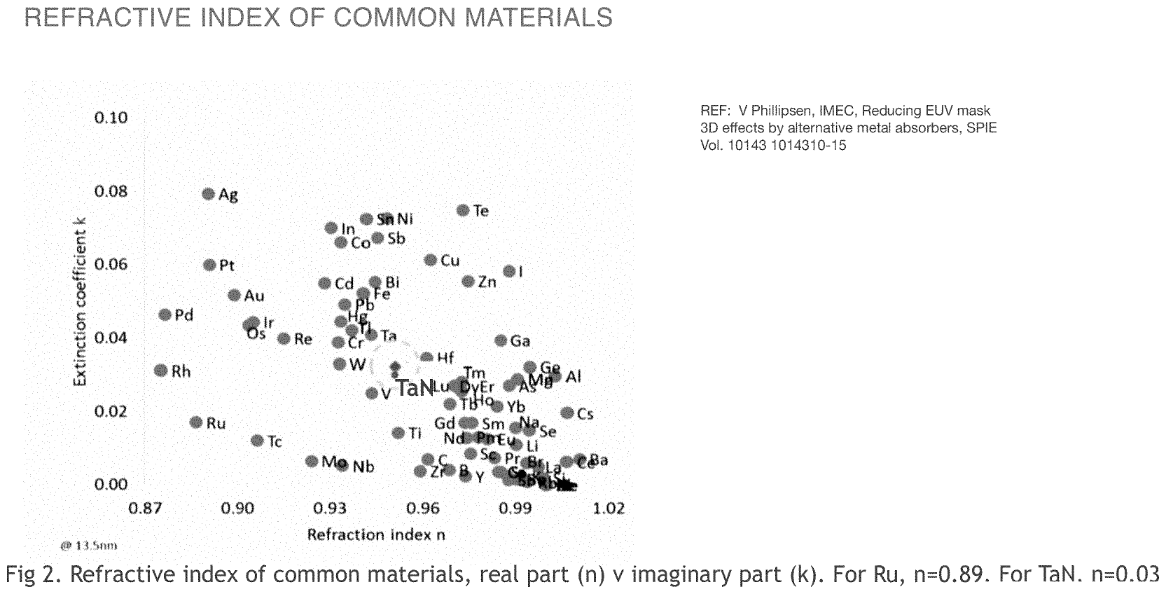

With reference to the examples and shown herein, the contemplated EUV mask has an increased NILS value as a function of a decreased “Zeff” or “Zeff” value as depicted in FIG. 2 for Mo—Si. Zeff refers to the effective plane from which the reflective wave arrives—e.g., the reflective ML starts to reflect light, after it propagates this plane. In certain embodiments, the contemplated EUV mask provided herein, has an increased NILS as a result of a decreased Zeff. In some embodiments, the Zeff is of or between 5 to 60 nm. The Zeff value corresponds to the reflective ML material. In certain embodiments, the Zeff may be of or between 5 to 60 nm, 5 to 50 nm, 10 to 50 nm, 10 to 40 nm, 15 to 40 nm, 15 to 30 nm, 15 to 25 nm, 18 to 25 nm, or 20 to 25 nm.

The substrate can include any suitable material. For example, the substrate material can include, but is not limited to, metal, metal alloys, semiconductors, composites, polymers, glass, and combinations thereof. In some embodiments, the substrate can be a metal, a metal alloy, a semiconductor, a composite, a polymer, a glass, and combinations thereof. In some embodiments, the substrate can be a semiconductor. In some embodiments, the substrate can be glass. In some embodiments, the substrate can be silicon dioxide, fused silica, quartz, Zerodur™, or other ultra low thermal expansion substrates.

The multilayer can include any suitable material capable of substantially reflecting extreme ultraviolet or X-ray radiation. Representative materials for the reflective multilayer include, but are not limited to, molybdenum, silicon, niobium, technetium, zirconium, ruthenium, beryllium, tungsten, boron carbide, carbon and others.

In certain embodiments, the multilayer comprises, consists essentially of, or consists of one or more metals. In certain embodiments, the multilayer comprises, consists essentially of, or consists of a metal having a refraction index (n) value of less than 1.00, less than 0.99, less than 0.98, less than 0.97, less than 0.96, or less than 0.95. In certain embodiments, the multilayer comprises, consists essentially of, or consists of a metal having an extinction coefficient (k) value of greater than zero, between 0 and 0.10, between 0 and 0.08, or between 0 and 0.06. In certain embodiments, the multilayer comprises, consists essentially of, or consists of one or more metals having the described refraction index and the described extinction coefficient. The multilayer can have from 2 to 1000 alternating layers. In certain embodiments, the multilayer comprises 10-60 bilayer pairs.

In certain embodiments, ML region comprises consists essentially of, or consists of one or more metal selected from Mo, Ru, Ta, Pt, Pd, Nb, Tc, Re, Os, W, C, Ag, or dielectrics thereof, Si, and air. In certain embodiments, the multilayer comprises, consists essentially of consists of Mo/Si, Ru/Si, Nb/Si, Tc/Si or Zirconium/Silicon, or combinations thereof. Two alternating layers may form a bilayer pair. There may be between 10 and 60 repeated bilayer pairs forming the reflective coating. In certain embodiments, the multilayer comprises alternating layers of each pair. In certain embodiments, the multilayer further comprises one or more barrier layers interspersed between each bilayer pair forming a trilateral repeating unit within the ML. Examples of barrier layers include boron carbide, or carbon and carbon based compounds. In certain embodiments, the multilayer further comprises one or more capping layers in contact with the top surface. Although Mo/Si is the typical combination, other material combinations, variations in thickness and reduced bilayer pairs can reduce Zeff.

The reflective region can be of any suitable thickness sufficient to reflect EUV or X-ray radiation. For example, the reflective layer can be from 50 to 1000 nm in thickness, or from 100 to 750 nm, or from 100 to 500 nm, or from 200 to 400 nm. The reflective layer can have a thickness of about 50 nm, or about 100, 150, 200, 250, 300, 350, 400, 450, 500, 600, 700, 800, 900, or about 1000 nm. In some embodiment, the reflective layer can have a thickness of about 300 nm.

In certain embodiments, the reflective region comprises air or silicon, or the reflective ML itself.

In particular embodiments, the EUV mask as disclosed and shown herein has a submerged non-reflective region in the reflective ML. EUV masks with submerged non-reflective regions have low Z (or low Zeff) mirrors. In certain embodiments, an EUV mask having a submerged non-reflective region renders the top surface planar, or two-dimensional. EUV masks with submerged non-reflective layers have low Z mirrors. In the submerged design, light can propagate and diffract at the submerged non-reflective region, but because the reflective ML is present around the diffraction, higher orders of double diffraction are suppressed.

In certain embodiments, the non-reflective regions comprise, consist essentially of, or essentially of, or consists of one or more metals selected from Mo, Ru, Ta, Pt, Pd, Nb, Tc, Re, Rh, Os, Ir, W, C, Ag or their oxides, nitrates, carbonates, fluorides, chlorides, sulfates, mixtures, compounds and alloys thereof. Some of these form a low n material, and some form a low n and high k material. Examples are shown in the table above.

The non-reflective regions of the multilayer can be of any suitable width and length to provide the desired image in the wafer. The non-reflective regions of the reflective multilayer can be of any suitable depth into the reflective layer. For example, the non-reflective portion can extend just a few nanometers into the reflective layer from the top surface of the reflective layer, or extend through the reflective layer to the substrate. In some embodiments, the non-reflective regions are from about 0 to about 100 nm deep from the top surface of the reflective layer, or from 1 to about 50 nm, or from 1 to about 25 nm, or from 1 to about 20 nm from the top surface of the reflective layer. In some embodiments, the non-reflective regions extend through the reflective layer to the substrate.

The difference in reflectivity between the reflective regions and non-reflective regions of the reflective layer create an image contrast sufficient to transfer the image from the mask to the wafer. The image contrast can be determined by dividing the reflectivity of the reflective region by the reflectivity of the non-reflective region, providing an image contrast of at least 10, or at least 50, 100, 200, 300, 400, 500, 1000, 2000, 3000, 4000, 5000, or at least about 10,000. In some embodiments, the reflectivity of radiation in the reflective region is at least 100 times greater than the reflectivity of radiation in the non-reflective region. In some embodiments, the reflectivity of radiation in the reflective region is at least 1000 times greater than the reflectivity of radiation in the non-reflective region. In some embodiments, the reflectivity of radiation in the reflective region is at least 10,000 times greater than the reflectivity of radiation in the non-reflective region.

As set forth in the exemplary EUV masks depicted herein, the height (h) and the depth (Zeff) of the non-reflective region submerged in the ML may be tuned to reduce the dose and render a throughput gain and increase in NILS. Accordingly, as shown herein, a decrease in Zeff of a submerged non-reflective region, renders an increase in NILS. Reduced Zeff also improves other important imaging lithography parameters such as dose to size and non-tele-centricity.

In further embodiments, the half pitch (HP) of a submerged non-reflective region relative to the height (h) affects the NILS of an EUV mask having a submerged or above surface absorber layer. As used herein, half-pitch (HP) refers to one half of the mean distance from the center of each non-reflective region to the center of the next non-reflective region in the ML. Accordingly, a decrease in the ratio of HP:h increases NILS. In a non-uniform diffraction grating, e.g. one in which the non-reflective features are not necessarily equally spaced, nor of equal period, the HP refers to the half pitch of the intended technology node e.g 16 nm HP or 8 nm or 45 nm HP.

In the EUV masks disclosed herein, the submerged absorber layer may have a ratio of HP:h ranging from 1:1.02 up to 1:50. Accordingly, a ratio of HP:h may range from 1:1.02 to 1:50; 1:1.05 to 1:40; 1:1.05 to 1:30; 1:1.05 to 1:20; 1:1.05 to 1:15; 1:1.05 to 1:10; 1.1.05 to 1:5; 1:1.05 to 1:4; 1:1.05 to 1:3; 1:1.05 to 1:2.5; 1:1.05 to 1:2.0; 1:1.05 to 1:1.9; 1:1.05 to 1:1.8; 1:1.05 to 1:1.7; 1:1.05 to 1:1.6; 1:1.05 to 1:1.5; 1:1.05 to 1:1.4; 1:1.05 to 1:1.3; 1:1.1 to 1:1.3; 1:1.1 to 1:1.25; 1:1.1 to 1:1.20; or 1:1.1 to 1:1.15.

In some embodiments, an EUV mask having a substrate and reflective ML as disclosed herein, and also includes a submerged or above surface absorber layer having a HP:h ratio of 1:1.02 up to 1:50, wherein the reflective ML includes a metal having a n value of less than or equal to about 1.0 and/or a k value of greater than zero (0.0), with a reflective ML material having a Zeff value of or between 5 to 60 nm. In still further embodiments, the EUV mask having a HP:h ratio of 1:1.02 up to 1:50, with reflective ML comprising a metal having an value of less than or equal to about 1.0 and/or a k value of greater than zero (0.0) and a Zeff value of or between 5 to 60 nm, also includes mask bias. Exemplary EUV masks with mask bias are disclosed herein. Mask bias can range from 1-5 nm, typically around 3 or 4 nm. The feature sizes of the reflecting or non-reflecting regions are expanded or contracted by these values in the lateral (x,y) plane.

In certain embodiments, the EUV mask comprises an absorber layer. In certain embodiments, the absorber layer comprises TaN. In certain embodiments, the absorber layer comprises Pt, Pd, Os, Ru, Rh, Ir, or oxides, nitrates, carbonates, fluorides, chlorides, sulfates, mixtures and alloys thereof. In certain embodiments, these absorber layers provide a low effective plane of reflection, Zeff, from the top surface of the multilayer, thereby enhancing NILS. Examples are shown in the table above.

In still other embodiments, the EUV mask as disclosed and shown herein is an “absorber free” or “absorber layer free” mask where air is used to create waveguide channeling and confinement of the light in the reflective ML. Without an absorber layer, there is an increased number of photos delivered to the wafer, thereby increasing reflectivity and increasing the clear region—e.g. an increase in Imax/o, thereby increasing the NILS and throughput gain of the mask. Furthermore, an absorber layer free mask is easier to fabricate. In some embodiments, the contemplated EUV mask as disclosed and depicted herein is NILS enhanced having a low Z mirror with an increase in photo delivery up to 3 times (3×).

In some embodiment, the contemplated EUV mask disclosed herein has an aspect ratio of or between 1:0.5 up to 1:50. For easier fabrication, a smaller aspect ratio is preferred. Accordingly, the contemplated EUV mask has an aspect ratio ranging from about 1:0.5 to 1:50; 1:0.5 to 1:40; 1:0.5 to 1:30; 1:0.5 to 1:20; 1:0.5 to 1:15; 1:0.5 to 1:10; 1:0.5 to 1:9; 1:0.5 to 1:8; 1:0.5 to 1:7; 1:0.5 to 1:6; 1:0.5 to 1:5; 1:0.5 to 1:4; 1:0.5 to 1:3; 1:0.5 to 1:2; 1:0.5 to 1:1.5; or 1:0.5 to 1:1.

### IV. Preparation

The multilayers and above surface diffraction grating described herein can be prepared according to techniques deemed suitable to the person of skill. In certain embodiments, a process for making a multilayer may be
1) Clean a fused silica, silicon, glass or low thermal expansion substrate.
2) Deposit an alternating combination of e.g. Mo and Si via e.g. ion beam deposition, PVD, Sputtering, MBE in a vacuum deposition tool on the substrate.
3) Deposit a capping layer, e.g ruthenium.
4) Deposit an absorber layer, e.g. PtO₂ or other low n material.
5) Coat top surface with photoresist or e-beam resist, e.g. through spin coating, vapor deposition, spraying or dip coating.
6) Use e-beam or optical lithography direct write to pattern resist into reflecting and above surface non-reflective regions, representing IC pattern.
7) Use reactive ion etch (RIE), atomic layer etch (ALE) or other etching technique to form the diffraction grating.
8) Remove photoresist or e-beam resist.

The multilayers and below surface diffraction grating described herein can be prepared according to techniques deemed suitable to the person of skill. In certain embodiments, a process for making a multilayer may be
1) Clean a fused silica, silicon, glass or low thermal expansion substrate.
2) Deposit an alternating combination of e.g. Mo and Si via e.g. ion beam deposition, PVD, Sputtering, MBE in a vacuum deposition tool on the substrate.
3) Deposit a capping layer, e.g ruthenium.
4) Coat top surface with photoresist or e-beam resist, e.g. through spin coating, vapor deposition, spraying or dip coating.
5) Use e-beam or optical lithography direct write to pattern resist into reflecting and submerged non-reflective regions, representing IC pattern
6) Use reactive ion etch (RIE), atomic layer etch (ALE) or other etching technique to form the diffraction grating.
7) Optionally deposit an absorber layer, e.g. PtO₂ or other low n material.
8) Remove photoresist or e-beam resist.
9) Planarize by polishing if necessary.

### I. Additional Mask Embodiments

The EUV mask of the present disclosure can include additional layers. In some embodiments, the EUV mask can also include a capping layer in contact with the top surface of the reflective layer. The capping layer can be prepared from any suitable material to protect the reflective layer and that is transparent to the EUV and X-ray radiation. Representative materials for the capping layer include ruthenium and any other transition metal. In some embodiments, the capping layer includes ruthenium.

The capping layer can be of any suitable thickness. For example, the capping layer can be from 1 to 100 nm thick, or from 1 to 10 nm thick. The capping layer can have a thickness of about 1 nm, or about 2, 3, 4, 5, 6, 7, 8, 9, or about 10 nm. In some embodiments, the capping layer can have a thickness of about 5 nm.

Use of a non-reflective region in the reflective layer avoids the need for an absorber layer on top of the reflective layer. In some embodiments, the present disclosure provides an EUV mask wherein an absorbance layer is not present. In some embodiments, the present disclosure provides an EUV mask substantially free of an absorbing layer. In some embodiments, the present disclosure provides an EUV mask substantially free of tantalum nitride.

A pellicle, if necessary, may be attached directly to the top surface of the EUV mask, or in close proximity of the top surface, and conformally to plane of a photomask containing a submerged non-reflecting region. Compared to the state of the art where the absorber plane is above the multilayer plane, the pellicle as applied to the present disclosure completely prevents particles entering the photomask on the reflective region. The pellicle may be vertically integrated as part of the full mask architecture.

The pellicle may be charged to deflect particles from landing on the pellicle or the mask.

The etched multilayer may optionally be filled with SiO₂ instead of Si.

After etching the non-reflective region, the top level of the multilayer in non-reflecting region is silicon or silicon dioxide (from oxidation). This reduces reflectivity further.

A pellicle, if necessary, may be attached directly to the top surface, or in close proximity of the top surface, and conformally to plane of a photomask containing a submerged non-reflecting region. Compared to the state of the art where the absorber plane is above the multilayer plane, the pellicle as applied to the present disclosure completely prevents particles entering the photomask on the reflective region. The pellicle may be vertically integrated as part of the full mask architecture.

The pellicle may be charged to deflect particles from landing on the pellicle or the mask.

### Examples

A mask example of the above surface variety may comprise the following: An LTEM substrate upon which a 40 bilayer pair Mo/Si (thickness 3 nm and 4 nm respectively) reflective coating is deposited by ion beam deposition. This is then followed by a 5 nm Ru capping layer. A 25 nm absorber layer of ruthenium oxide is then deposited on top of the capping layer. The absorber layer is patterned in to a diffraction grating using a mask e beam writer. The diffraction grating is created by etching the absorber layer using a refractive ion etching down to the capping layer.

A mask example of the submerged variety may comprise the following: An LTEM substrate upon which a 40 bilayer pair Mo/Si (thickness 3 nm and 4 nm respectively) reflective coating is deposited by ion beam deposition. This is then followed by a 5 nm Ru capping layer. The capping layer is patterned in to a diffraction grating using a mask e beam writer. The diffraction grating is created by etching the capping layer and multilayer using a refractive ion etching for approximately 18 nm. An 18 nm layer of platinum oxide is then deposited on top of the capping layer. The remaining e beam resist is then removed leaving sharp contrast edges for the reflection and non-reflective regions.

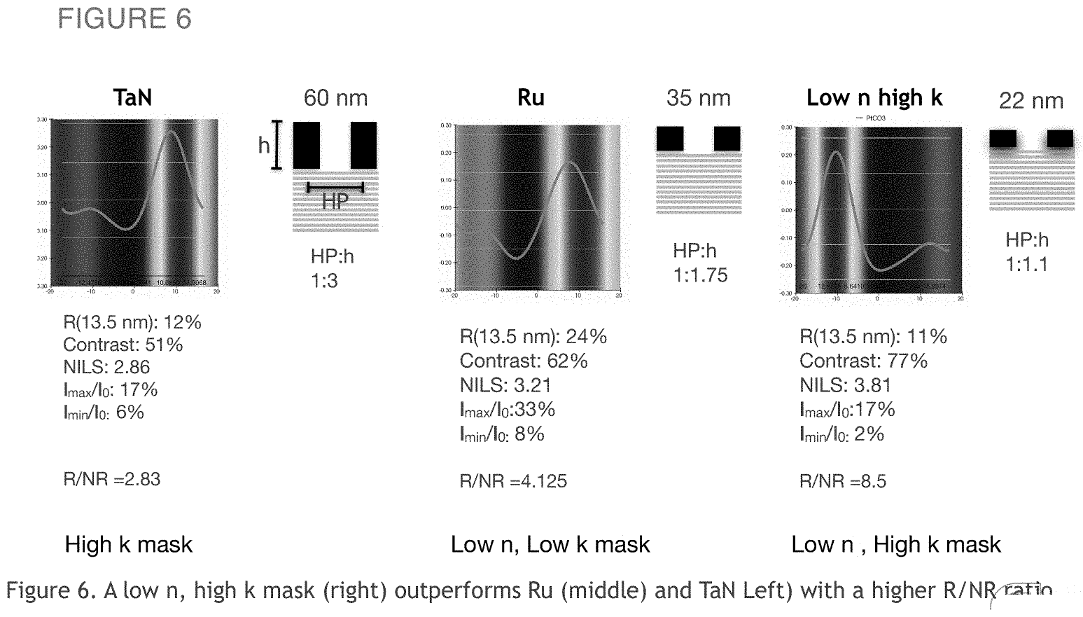

Simulation results are shown in FIGS. 5-8. Iₘₐₓ/I₀ describes the max intensity Iₘₐₓ at the reflecting region relative to the incident light I₀. Iₘᵢₙ/I₀ describes the min intensity Iₘₐₓ at the non-reflecting region relative to the incident light I₀. The ratio of these two values is the ratio of R/NR or reflectivity in the reflecting (R) to non-reflecting regions. FIG. 6 shows that Ru leaks in the non-reflecting region, with 8% reflectivity emerging from this region. However, the low n high k mask of 22 nm of platinum oxide only has 2% reflectivity in the non-reflectivity region, resulting in a higher R/NR ratio 8.5, contrast and NILS value. Similarly submerged diffraction gratings are shown in FIG. 5. A Low Zeff mirror shown here produces a very high NILS value of 7.22 and almost 20× more light in the reflecting region compared to the non-reflecting region. Dose is inversely proportional to square of NILS. A doubling of NILS results in 4× reduction of dose and a 4× throughput gain.

Although the foregoing disclosure has been described in some detail by way of illustration and Example for purposes of clarity of understanding, one of skill in the art will appreciate that certain changes and modifications may be practiced within the scope of the appended claims. In addition, each reference provided herein is incorporated by reference in its entirety to the same extent as if each reference was individually incorporated by reference. Where a conflict exists between the instant application and a reference provided herein, the instant application shall prevail.

1. An extreme ultraviolet mask, comprising:
a substrate; and
a multilayer (ML) region comprising a reflective (R) region with a non-reflective (NR) region,
wherein the ML region comprises a bottom surface in contact with the substrate and a top surface, and
wherein the reflectivity of the reflective (R) region is at least 4.2 times greater than the reflectivity of the non-reflective (NR) region.

2. The mask of claim 1, wherein the NR region comprises a metal having a refraction index (n) value of less than 0.89, less than 0.88, less than 0.87, less than 0.86, less than 0.85, or less than 0.84.

3. The mask of claim 1, wherein the R region comprises air, silicon, silicon dioxide, or other transparent material.

4. The mask of claim 1, wherein the NR region comprises a metal having an extinction coefficient (k) value of greater than zero, between 0.03 and 0.10, between 0.03 and 0.08, or between 0.03 and 0.06.

5. The mask of claim 1, wherein the ML region comprises one or more metal selected from Mo, Ru, Ta, Pt, Pd, Nb, Tc, Re, Rh, Os, W, C, Ag, and/or oxides, nitrates, carbonates, substrates, mixtures, compounds and alloys, or dielectrics thereof, Si, and air.

6. The mask any of claim 1, wherein the submerged NR region has a height (h) and a half pitch (HP) with respect to the ML, region, wherein the ratio of HP:h is selected from 1.1.02 to 1.50.

7. The mask of claim 1 having a Zeff value selected from 5 to 60 nm.

8. The mask of claim 1 further comprising mask bias.

9. The mask of claim 1 where the Reflective (R) or non-Reflective (NR) regions are submerged below the surface of the multilayer.

10. The mask of claim 1, wherein the radiation has a wavelength from 250 nm to 1 nm.

11. The mask of claim 1, wherein the radiation has a wavelength from 124 nm to 10 nm.

12. The mask of claim 1, wherein the radiation has a wavelength of about 13.5 nm.

13. The mask of claim 1, wherein the reflective layer comprises multilayers of molybdenum and silicon, ruthenium, niobium, technetium, boron carbide, or tungsten and carbon.

14. The mask of claim 1, wherein the mask is used in conjunction with a pellicle.

15. The mask of claim 1, wherein the non-reflecting (NR) region comprises a metal including molybdenum, niobium, molybdenum carbide, technetium, ruthenium, zirconium, platinum, palladium, osmium, rhodium, rhenium, iridium or their oxides, sulfates, carbonates or nitrates or mixtures and compounds thereof.

16. The mask of claim 1 where the reflecting region (R) comprises silicon, air, silicon dioxide, or a reflective multilayer, Mo/Si or any transparent material.

17. The mask of claim 1, further comprising a capping layer in contact with the top surface of the reflective layer.

18. The mask of claim 1, wherein an absorber layer is not present.

19. The mask of claim 1, wherein the mask is a phase shifting mask.
